(19) United States
(12) Patent Application Publication
(10) Pub. No.: US 2023/0271513 A1
(43) Pub. Date: Aug. 31, 2023

(54) Method and System for Coordinating Operation of Fuel Cell System and Traction Battery to Improve Durability and Fuel Economy

(71) Applicant: Ford Global Technologies, LLC, Dearborn, MI (US)

(72) Inventors: Walter Joseph Ortmann, Saline, MI (US); Jason Meyer, Canton, MI (US)

(73) Assignee: Ford Global Technologies, LLC, Dearborn, MI (US)

(21) Appl. No.: 17/676,634

(22) Filed: Feb. 21, 2022

(51) Int. Cl. B60L 53/00; B60L 50/75; B60L 58/12; B60L 58/30

(52) U.S. Cl. CPC B60L 53/00; B60L 50/75; B60L 58/12; B60L 58/30

(57) ABSTRACT

A vehicle includes a fuel cell system (FCS), a traction battery, and a controller. The controller controls the FCS to output a constant amount of power throughout a vehicle trip. Responsive to a demanded power greater than the constant amount, the controller controls the traction battery to output an amount of power commensurate with a difference between the demanded power and the constant amount.

### TECHNICAL FIELD

The present invention relates to controlling a fuel cell system and a traction battery in providing electrical power for vehicle propulsion.

### BACKGROUND

A type of fuel cell electric vehicle (FCEV) includes a fuel cell system (FCS) and a traction battery. The FCS converts chemical energy of a fuel, e.g., hydrogen, and an oxidizing agent, e.g., oxygen, into electrical energy, with water as a byproduct. The traction battery stores electrical energy. Electrical power from the FCS and electrical power from the traction battery are used for propelling the vehicle.

### SUMMARY

A vehicle includes a fuel cell system (FCS), a traction battery, and a controller. The controller is configured to control the FCS to output a constant amount of power throughout a vehicle trip. The controller is further configured to, responsive to a demanded power greater than the constant amount, control the traction battery to output an amount of power commensurate with a difference between the demanded power and the constant amount.

The controller may be further configured to, responsive to a demanded power less than the constant amount, control the traction battery to receive a portion of the power from the FCS commensurate with a difference between the constant amount and the demanded power.

The controller may be further configured to, responsive to a state-of-charge (SOC) of the traction battery during the vehicle trip either becoming greater than a high threshold or less than a low threshold, readjust the FCS to output a power commensurate with a sum of the constant amount and a SOC correction power term. The SOC correction power term may be dependent on the SOC of the traction battery and not on demanded power.

The controller may be further configured to, responsive to the SOC of the traction battery during the vehicle trip reverting to being not greater than the high threshold and not lesser than the low threshold, readjust the FCS to output a power commensurate with the constant amount.

The controller may be further configured to, prior to the vehicle trip, predict a value of the constant amount of power based on an amount of power expected to be required for propelling the vehicle during the vehicle trip and an expected duration of the vehicle trip. The controller may be further configured to estimate the amount of power expected to be required for propelling the vehicle during the vehicle trip and the expected duration of the vehicle trip based in part on historical usage data of the vehicle.

The controller may be further configured to select as a value of the constant amount of power the value which results in a highest fuel economy of the FCS.

A method for a vehicle having an FCS and a traction battery includes controlling the FCS to output a constant fuel cell power throughout a vehicle trip for propelling the vehicle. The method further includes, responsive to a demanded power greater than the fuel cell power during the vehicle trip, controlling the traction battery to output a traction battery power for propelling the vehicle commensurate with a difference between the demanded power and the fuel cell power.

A system for use with an FCS and a traction battery of a vehicle includes a controller configured to control the FCS to output a constant fuel cell power throughout a vehicle trip for propelling the vehicle. The controller is further configured to, responsive to a demanded power greater than the fuel cell power during the vehicle trip, control the traction battery to output a traction battery power for propelling the vehicle commensurate with a difference between the demanded power and the fuel cell power.

### BRIEF DESCRIPTION OF THE DRAWINGS

FIG. 1 illustrates a block diagram of a fuel cell electric vehicle (FCEV) having a fuel cell system (FCS) and a traction battery both for providing electrical power for vehicle propulsion;

FIG. 2 illustrates a process diagram for coordinating operation of the FCS and the traction battery in providing electrical power for vehicle propulsion;

FIG. 3 illustrates a flowchart depicting operation of a method and a system for controlling the FCS and the traction battery in providing electrical power to propel the FCEV in a manner in which durability and fuel economy of the FCS is improved; and

FIG. 4 illustrates a flowchart depicting further operation of the method and the system for controlling the FCS and the traction battery.

### DETAILED DESCRIPTION

Detailed embodiments of the present invention are disclosed herein; however, it is to be understood that the disclosed embodiments are merely exemplary of the present invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

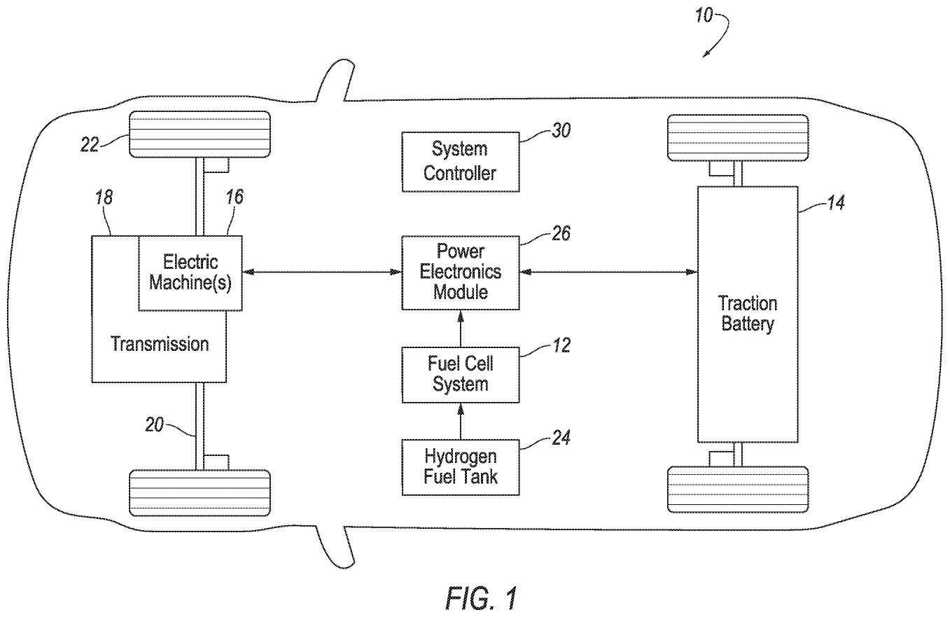

Referring now to FIG. 1, a block diagram of an exemplary fuel cell electric vehicle (FCEV) 10 having a fuel cell system (FCS) 12 and a traction battery 14 is shown. FCS 12 and traction battery 14 are individually operable for providing electrical power for propulsion of FCEV 10.

FCEV 10 further includes one or more electric machines 16 mechanically connected to a transmission 18. Electric machine 16 is capable of operating as a motor and as a generator. Transmission 18 is mechanically connected to a drive shaft 20 mechanically connected to wheels 22 of FCEV 10. Electric machine 16 can provide propulsion and slowing capability for FCEV 10. Electric machine 16 acting as a generator can recover energy that may normally be lost as heat in a friction braking system.

FCS 12 includes one or more fuel cell stacks comprised of fuel cells. FCS 12 is configured to convert hydrogen from a hydrogen fuel tank 24 of FCEV 10 into electrical power. Electrical power from FCS 12 is for use by electric machine 16 for propelling FCEV 10.

FCS 12 is electrically connected to electric machine 16 via a power electronics module 26 of FCEV 10. Power electronics module 26, having an inverter or the like, provides the ability to transfer electrical power from FCS 12 to electric machine 16. For example, FCS 12 provides direct current (DC) electrical power while electric machine 16 may require three-phase alternating current (AC) electrical power to function. Power electronics module 26 converts the electrical power from FCS 12 into electrical power having a form compatible for operating electric machine 16. In this way, FCEV 10 is configured to be propelled with use of electrical power from FCS 12.

Traction battery 14 stores electrical energy for use by electric machine 16 for propelling FCEV 10. Traction battery 14 is also electrically connected to electric machine 16 via power electronics module 26. Power electronics module 26 provides the ability to bi-directionally transfer electrical power between traction battery 14 and electric machine 16. For example, traction battery 14 also provides DC electrical power while electric machine 16 may require the three-phase AC electrical power to function. Power electronics module 26 converts the electrical power from traction battery 14 into electrical power having the form compatible for operating electric machine 16. In this way, FCEV 10 is further configured to be propelled with the use of electrical power from traction battery 14.

Further, in a regenerative mode, power electronics module 26 converts AC electrical power from electric machine 16 acting as a generator to the DC electrical power form compatible with traction battery 14. Similarly, traction battery 14 may receive electrical power from FCS 12 via power electronics module 26. For instance, when FCS 12 is providing electrical power for propelling FCEV 10, any excess electrical power from the FCS not used in propelling the FCEV may be received by traction battery 14 via power electronics module 26.

FCS 12 and traction battery 14 may have one or more associated controllers to control and monitor the operation thereof. The controllers can be microprocessor-based devices. The controllers may communicate via a serial bus (e.g., Controller Area Network (CAN)) or via discrete conductors.

For example, a vehicle system controller (VSC) 30 is configured to coordinate the operation of FCS 12 and traction battery 14 in providing electrical power for propulsion of FCEV 10 and may be further configured to control the FCS and/or the traction battery accordingly. Vehicle system controller 30 (“controller”) can be considered as being one controller or multiple individual controllers for controlling FCS 12 and traction battery 14.

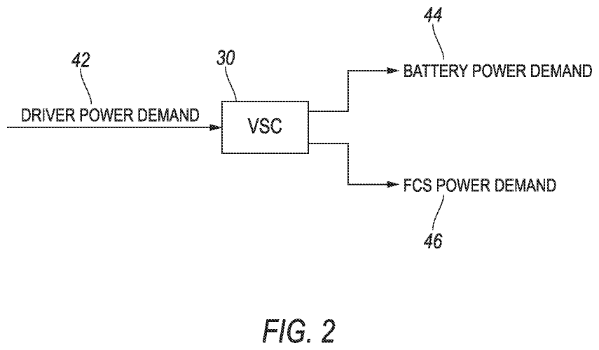

Referring now to FIG. 2, with continual reference to FIG. 1, a process diagram 40 for coordinating operation of FCS 12 and traction battery 14 in providing electrical power for propulsion of FCEV 10 is shown. In response to a driver power demand (request) 42 for propelling FCEV 10, controller 30 interprets and splits the driver power demand into a traction battery power demand (request) 44 and an FCS power demand (request) 46. In turn, traction battery 14 is controlled by controller 30 to provide (i.e., output, deliver, etc.) electrical power commensurate with battery power request 44 for use in propelling FCEV 10. Similarly, FCS 12 is controlled by controller 30 to provide (i.e., output, deliver, etc.) electrical power satisfying FCS power request 46 for use in propelling FCEV 10.

Controller 30, in accordance with embodiments of the present invention, controls FCS 12 and traction battery 14 in providing electrical power to propel FCEV 10 in a manner in which durability and fuel economy of the FCS is improved.

As an overview, in operation of FCEV 10, a driver provides a dynamic request for propulsive torque (i.e., driver power demand 42) that the powertrain of the FCEV is to meet. The response time of FCS 12 may be relatively too slow to provide the dynamic torque. Accordingly, controller 30 controls traction battery 14 to “fill-in” the requested power. The strategy employed by controller 30 is responsive to the driver request.

The strategy employed by an ordinary controller is also responsive to the driver request. However, when a powertrain demand is increased, the ordinary controller would control FCS 12 to increase the electrical power provided by the FCS (i.e., the fuel cell power) up to a maximum allowable and would control traction battery 14 to provide the remaining electrical power required for meeting the powertrain demand.

In this regard, historically in internal combustion engine (ICE) powertrains, dynamic driver demand is met by changing the engine power and torque to meet the desired demand. The engine has a dynamic response time that is capable of meeting the demand in an acceptable manner. In hybrid vehicles having an engine and a traction battery, the electric machine (i.e., the motor) is used to assist in placing the powertrain in a more optimal operating point but for significant demand changes, the engine power is changed quickly. An FCS cannot handle this fast-changing power demand without degradation to its durability. Therefore, in addition to an FCS, an FCEV includes a traction battery which can meet the dynamic needs of the powertrain. However, unless the FCS is controlled differently, the FCS will change its fuel cell power as quickly as possible when the driver demand changes.

From a durability and fuel economy standpoint, FCS 12 is most optimal when operating at a near steady state condition (i.e., when outputting a near constant amount of electrical power). Accordingly, in accordance with embodiments of the present invention, controller 30 controls FCS 12 to operate at a near steady state power level and controls traction battery to handle all transient powers. As such, rather than controlling FCS 12 to change its output power with driver demand, controller 30 places the FCS in the near steady state condition and controls traction battery 14 to change its output power with the driver demand. As a result, controller 30 controls FCS 12 to provide a near constant amount of electrical power, and in response to a driver demand requiring a different amount of electrical power than the amount of electrical power provided by the FCS, controller 30 controls traction battery 14 to provide, or absorb as the case may be, the remaining difference in electrical power.

In embodiments, controller 30 estimates the near steady state power level at which FCS 12 is to be set during a given vehicle trip based on a predicted average power of the vehicle trip. Controller 30 may use historic data and connectivity among other inputs to predict the average power of the vehicle trip.

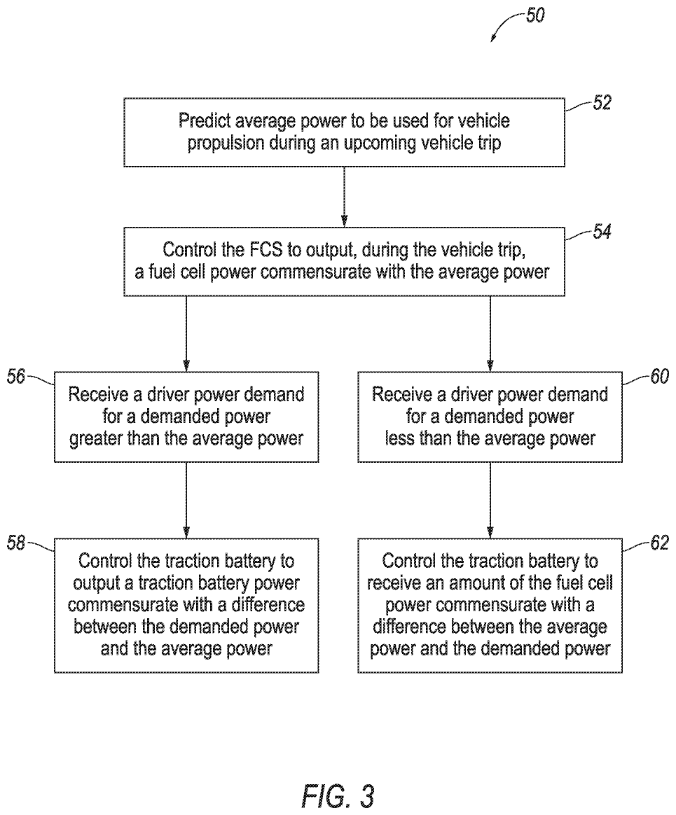

Referring now to FIG. 3, with continual reference to FIGS. 1 and 2, a flowchart 50 depicting operation of a method and a system for controlling FCS 12 and traction battery 14 in providing electrical power to propel FCEV 10 in a manner in which durability and fuel economy of the FCS is improved is shown. Controller 30 implements the operation.

The operation begins with controller 30 estimating an average power to be used for propelling FCEV 10 during an upcoming vehicle trip, as indicated in block 52. The estimated average power and torque may be based on learnings from past usage (historic data), connectivity to determine expected grade, speed, weather (e.g., head winds, temperature, sun load), traffic, etc., trailer connection and historical trailer usage, estimate/measurement of payload, climate loads, and the like.

Controller 30 controls FCS 12 to output throughout the vehicle trip an electrical power (“fuel cell power”) commensurate with the average power, as indicated in block 54. FCS 12 outputs the fuel cell power to the powertrain of FCEV 10 for use in propelling the FCEV in response to a driver power demand 42. As such, based on an estimate of an expected average power to be used for propelling FCEV 10 during the vehicle trip, controller 30 operates FCS 12 at this steady state operating point through that specific vehicle trip. Accordingly, while the demanded power of driver power demand 42 for propelling FCEV 10 is commensurate with the average power, the fuel cell power from FCS 12 satisfies the driver power demand and no battery power from traction battery 14 is needed for propelling the FCEV.

Of course, in controlling FCS 12 to output a fuel cell power commensurate with the average power, controller 30 may control the FCS to output a fuel cell power deviating within a relatively small range of the average power whereby the FCS is still effectively operated at the steady state operating point.

On the one hand, during the vehicle trip, controller 30 may receive a driver power demand 42 for a demanded power greater than the average power, as indicated in block 56. The fuel cell power from FCS 12 is insufficient for propelling FCEV 10 according to the greater demanded power as the fuel cell power is commensurate with the average power. Thus, a difference in power between the greater demanded power and the average power (i.e., a difference between the greater demanded power and the fuel cell power) is further required for propelling FCEV 10 according to the greater demanded power.

In this case, controller 30 controls traction battery 14 to output an electrical power (“traction battery power”) commensurate with the difference in power between the greater demanded power and the average power, as shown in block 58. The sum of the fuel cell power, outputted from FCS 12 for propelling FCEV 10, and the traction battery power, outputted from traction battery 14 for also propelling the FCEV, is equal to the greater demanded power. As such, controller 30 controls traction battery 14 to output the difference in power between the greater power and the average power while maintaining FSC 12 to output the average power.

On the other hand, during the vehicle trip, controller 30 may receive a driver power demand 42 for a demanded power less than the average power, as indicated in block 60. The fuel cell power from FCS 12 is more than required for propelling FCEV 10 according to the lesser demanded power as the fuel cell power is commensurate with the average power. Thus, a difference in power between average power and the lesser demanded power (i.e., a difference between the fuel cell power and the lesser demanded power) is not required for propelling FCEV 10 according to the lesser demanded power.

In this case, controller 30 controls traction battery 14 to receive from FCS 12 an amount of the fuel cell power commensurate with the difference in power between the average power and the lesser demanded power, as shown in block 62. The fuel cell power, outputted from FCS 12, is equal to the sum of the amount of the fuel cell power used in propelling FCEV 10 and the amount of the fuel cell power used in charging traction battery 14. As such, controller 30 controls traction battery 14 to receive the difference in power between the average power and the lesser power while maintaining FSC 12 to output the average power.

As set forth, controller 30 controls FCS 12 to operate at a steady state operating point throughout a vehicle trip, in which the steady state operating point is based on an estimate of an expected average power for the vehicle trip, and controls traction battery 14 to dynamically meet driver demanded power and torque during the vehicle trip. Controller 30 thereby takes advantage of the fact that traction battery 14 is a relatively large and powerful source of electrical energy capable of handling high sustainable loads. By operating near the average power demand for the vehicle trip, the powertrain is expected to have improved durability through lower number of low, high, low cycles and should maintain a relatively high average efficiency. In this way, controller 30 coordinates operation of FCS 12 and traction battery 14 in providing electrical power to propel FCEV 10 in a manner in which durability and fuel economy of the FCS is improved.

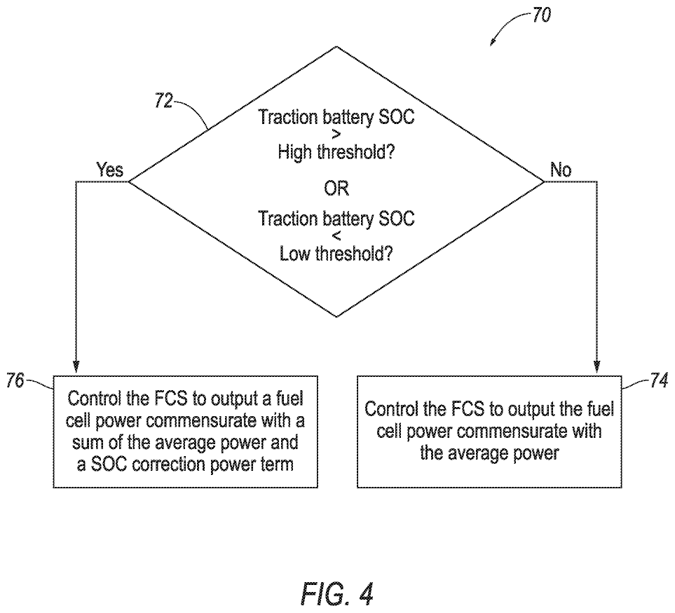

Referring now to FIG. 4, with continual reference to FIGS. 1, 2, and 3, a flowchart 70 depicting further operation of the method and the system for controlling FCS 12 and traction battery 14 is shown. Controller 30 implements the operation.

While traction battery 14 can provide fill-in power for high power and lower power transients, the battery capacity is not sufficient to indefinitely provide fill-in power. Accordingly, pursuant to the operation depicted in flowchart 70, controller 30 is configured to provide a mechanism for managing the state-of-charge (SOC) of traction battery 14 within a drive cycle (i.e., during the vehicle trip).

In operation, throughout the vehicle trip, controller 30 checks whether the SOC of traction battery 14 is above or below a set of desired thresholds, as indicated in decision block 72. On the one hand, while the SOC of traction battery 14 is not above or below the set of desired thresholds, controller 30 controls FCS 12 to output a fuel cell power commensurate with the average power, as indicated in block 74. On the other hand, while the SOC of traction battery 14 is above or below the set of desired thresholds, controller 30 controls FCS to output a fuel cell power commensurate with a sum of the average power and a SOC correction power term. The SOC correction power term is similar to the SOC correction used in a hybrid electric vehicle having an engine and a traction battery but depends predominantly on the SOC of traction battery 14 as opposed to depending on the traction battery SOC and the driver demand. As such, in this case, the fuel cell power command is set to the average predicted power plus an SOC correction term.

By operating FCS 12 at the average predicted power, the fuel economy can be optimized. While an internal combustion engine becomes more efficient at higher loads, FCS 12 is most efficient at low loads. Accordingly, controller 30 may be further configured to operate FCS 12 at the lowest possible power point that optimizes fuel economy.

As described, embodiments of the present invention provide a method and a system of operating a fuel cell system to improve durability and fuel economy. The improved durability is due in part to lower fuel cell power cycling and the improved fuel efficiency is due in part to operation at the best fuel efficiency.

While exemplary embodiments are described above, it is not intended that these embodiments describe all possible forms of the present invention. Rather, the words used in the specification are words of description rather than limitation, and it is understood that various changes may be made without departing from the spirit and scope of the present invention. Additionally, the features of various implementing embodiments may be combined to form further embodiments of the present invention.

What is claimed is:

1. A vehicle comprising:
a fuel cell system (FCS);
a traction battery; and
a controller configured to control the FCS to output a constant amount of power throughout a vehicle trip and, responsive to a demanded power greater than the constant amount, to control the traction battery to output an amount of power commensurate with a difference between the demanded power and the constant amount.

2. The vehicle of claim 1 wherein:
the controller is further configured to, responsive to a demanded power less than the constant amount, control the traction battery to receive a portion of the power from the FCS commensurate with a difference between the constant amount and the demanded power.

3. The vehicle of claim 1 wherein:
the controller is further configured to, responsive to a state-of-charge (SOC) of the traction battery during the vehicle trip either becoming greater than a high threshold or less than a low threshold, readjust the FCS to output a power commensurate with a sum of the constant amount and a SOC correction power term.

4. The vehicle of claim 3 wherein:
the SOC correction power term is dependent on the SOC of the traction battery and not on demanded power.

5. The vehicle of claim 3 wherein:
the controller is further configured to, responsive to the SOC of the traction battery during the vehicle trip reverting to being not greater than the high threshold and not lesser than the low threshold, readjust the FCS to output a power commensurate with the constant amount.

6. The vehicle of claim 1 wherein:
the controller is further configured to, prior to the vehicle trip, predict a value of the constant amount of power based on an amount of power expected to be required for propelling the vehicle during the vehicle trip and an expected duration of the vehicle trip.

7. The vehicle of claim 6 wherein:
the controller is further configured to estimate the amount of power expected to be required for propelling the vehicle during the vehicle trip and the expected duration of the vehicle trip based in part on historical usage data of the vehicle.

8. The vehicle of claim 1 wherein:
the controller is further configured to select as a value of the constant amount of power the value which results in a highest fuel economy of the FCS.

9. A method for a vehicle having a fuel cell system (FCS) and a traction battery, the method comprising:
controlling the FCS to output a constant fuel cell power throughout a vehicle trip for propelling the vehicle; and
responsive to a demanded power greater than the fuel cell power during the vehicle trip, controlling the traction battery to output a traction battery power for propelling the vehicle commensurate with a difference between the demanded power and the fuel cell power.

10. The method of claim 9 further comprising:
responsive to a demanded power less than the fuel cell power during the vehicle trip, controlling the traction battery to receive a portion of the fuel cell power commensurate with a difference between the fuel cell power and the demanded power.

11. The method of claim 9 further comprising:
responsive to a state-of-charge (SOC) of the traction battery during the vehicle trip either becoming greater than a high threshold or less than a low threshold, controlling the FCS to increase the fuel cell power by a SOC correction power term.

12. The method of claim 11 wherein:
the SOC correction power term is dependent on the SOC of the traction battery and not on demanded power.

13. The method of claim 11 further comprising:
responsive to the SOC of the traction battery during the vehicle trip reverting to being not greater than the high threshold and not lesser than the low threshold, controlling the FCS to decrease the fuel cell power by the SOC correction power term.

14. A system for use with a fuel cell system (FCS) and a traction battery of a vehicle, the system comprising:
a controller configured to control the FCS to output a constant fuel cell power throughout a vehicle trip for propelling the vehicle; and
the controller is further configured to, responsive to a demanded power greater than the fuel cell power during the vehicle trip, control the traction battery to output a traction battery power for propelling the vehicle commensurate with a difference between the demanded power and the fuel cell power.

15. The system of claim 14 wherein
the controller is further configured to, responsive to a demanded power less than the fuel cell power during the vehicle trip, control the traction battery to receive a portion of the fuel cell power commensurate with a difference between the fuel cell power and the demanded power.

16. The system of claim 14 wherein:
the controller is further configured to, responsive to a state-of-charge (SOC) of the traction battery during the vehicle trip either becoming greater than a high threshold or less than a low threshold, control the FCS to increase the fuel cell power by a SOC correction power term.

17. The system of claim 16 wherein:
the SOC correction power term is dependent on the SOC of the traction battery and not on demanded power.

18. The system of claim 16 wherein:
the controller is further configured to, responsive to the SOC of the traction battery during the vehicle trip reverting to being not greater than the high threshold and not lesser than the low threshold, control the FCS to decrease the fuel cell power by the SOC correction power term.

19. The system of claim 14 wherein:
the controller is further configured to, prior to the vehicle trip, predict a value of the constant fuel cell power based on amount of power expected to be required for propelling the vehicle during the vehicle trip and an expected duration of the vehicle trip.

20. The system of claim 14 wherein:
the controller is further configured to select as a value of the constant fuel cell power the value which results in a highest fuel economy of the FCS.
